(19) United States
(12) Patent Application Publication
(10) Pub. No.: US 2023/0069716 A1
(43) Pub. Date: Mar. 2, 2023

(54) METAL INTERCONNECT STRUCTURES AND METHODS OF FABRICATING THE SAME

(71) Applicant: Taiwan Semiconductor Manufacturing Company Limited, Hsinchu (TW)

(72) Inventors: Jheng-Hong JIANG, Hsinchu (TW); Shing-Huang WU, Hsinchu (TW); Chia-Wei LIU, Zhubei City (TW)

(21) Appl. No.: 17/460,589

(22) Filed: Aug. 30, 2021

(51) Int. Cl. H01L 21/768; H01L 23/522

(52) U.S. Cl. CPC H01L 21/76877; H01L 21/7684; H01L 21/76832; H01L 21/76847; H01L 23/5228

(57) ABSTRACT

Interconnect structures and methods of forming interconnect structures are disclosed that provide decreased risk of unwanted via formation through interconnect-level dielectric layers. A method of forming an interconnect structure includes forming first and second dielectric layers over a first metal interconnect feature, where the dielectric layers include localized elevated regions caused by a hillock in the first metal interconnect feature. A planarization process removes the localized elevated region of the second dielectric layer, and third and fourth dielectric layers are formed over the planar upper surface of the second dielectric layer. An etching process through the third and fourth dielectric layers, and into the second dielectric layer, provides a trench having a planar bottom surface. A second metal interconnect feature is formed within the trench, where the second metal interconnect feature includes a planar bottom surface overlying the localized elevated region of the first dielectric layer and the hillock.

### BACKGROUND

The semiconductor industry has continually grown due to continuous improvements in integration density of various electronic components, e.g., transistors, diodes, resistors, capacitors, etc. As feature sizes have become smaller and the integration density of integrated circuit (IC) devices has increased, the fabrication of metal interconnect structures for IC devices has faced increasing challenges. There is a continuing need for improvements in metal interconnect fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-section view of an exemplary structure of an integrated circuit device according to various embodiments of the present disclosure.

FIG. 2 is a vertical cross-section view of an exemplary structure having a first metal interconnect feature having a hillock according to an embodiment of the present disclosure.

FIG. 3 is a vertical cross-section view of the exemplary structure showing a first dielectric layer formed over the first metal interconnect feature, and a second dielectric layer formed over the first dielectric layer according to an embodiment of the present disclosure.

FIG. 4 is a vertical cross-section view of the exemplary structure showing a patterned mask over the upper surface of the second dielectric layer according to an embodiment of the present disclosure.

FIG. 5 is a vertical cross-section view of the exemplary structure showing a via opening formed through the second dielectric layer according to an embodiment of the present disclosure.

FIG. 6 is a vertical cross-section view of the exemplary structure showing the via opening extended through the first dielectric layer to expose an upper surface of the first metal interconnect feature according to an embodiment of the present disclosure.

FIG. 7 is a vertical cross-section view of the exemplary structure showing a barrier layer deposited on the second dielectric layer and the sidewalls and bottom surface of the via opening, and a metallic fill layer deposited over the upper surface of the barrier layer and filling a remaining volume of the via opening according to an embodiment of the present disclosure.

FIG. 8 is a vertical cross-section view of the exemplary structure after a planarization process to remove the elevated region of the second dielectric layer and portions of the metallic fill layer and the barrier layer from above the upper surface of the second dielectric layer according to an embodiment of the present disclosure.

FIG. 9 is a vertical cross-section view of the exemplary structure showing a third dielectric layer formed over the second dielectric layer and a conductive via according to an embodiment of the present disclosure.

FIG. 10 is a vertical cross-section view of the exemplary structure showing a fourth dielectric layer formed over an upper surface of the third dielectric layer, and a patterned mask formed over the fourth dielectric layer according to an embodiment of the present disclosure.

FIG. 11 is a vertical cross-section view of the exemplary structure showing trenches formed in first and second regions of the exemplary structure according to an embodiment of the present disclosure.

FIG. 12 is a vertical cross-section view of the exemplary structure showing the trenches extended through the third dielectric layer and into the second dielectric layer according to an embodiment of the present disclosure.

FIG. 13 is a vertical cross-section view of the exemplary structure showing a barrier layer on the fourth dielectric layer and on the sidewalls and bottom surfaces of the trenches according to an embodiment of the present disclosure.

FIG. 14 is a vertical cross-section view of the exemplary structure showing a metallic fill layer deposited over the upper surface of the barrier layer and filling a remaining volume of the trenches according to an embodiment of the present disclosure.

FIG. 15 is a vertical cross-section view of the exemplary structure showing a second metal interconnect feature formed in the first region of the exemplary structure and a third metal interconnect feature formed in the second region of the exemplary structure according to an embodiment of the present disclosure.

FIG. 16 is a flow chart showing a method of forming an interconnect structure for an integrated circuit device according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments of the present disclosure relate to metal interconnect structures for integrated circuit (IC) devices, and methods of fabricating metal interconnect structures.

With increasing device density and decreasing device feature size, forming metal interconnect structures has become increasingly challenging. In a typical circuit design, there may be variations in the pattern density within different regions of an IC. For example, regions of the IC having the highest pattern density are often in the central portion of the IC. Regions of low pattern density are often in the peripheral region(s) of the IC. These regional variations in pattern density of the IC may result in regional variations in the etch rate of material(s) during etching processes, such as during the etching of dielectric material to form interconnect structures of the IC. The regional variation in etch rate of an IC is sometimes referred to as the pattern density loading effect. In general, regions of the IC having the highest pattern density may have a significantly lower etching rate than regions of low pattern density.

In order to account for these regional variations in etch rate due to the pattern density loading effect, the etch recipes used during formation of the interconnect structure are typically optimized for the regions of highest pattern density in order to avoid instances of under-etching. Under-etching may result in incomplete formation of conductive vias, for example, which may negatively impact IC performance and functionality. However, by optimizing the etch recipe for regions of high pattern density, the etching process may result in over-etching, i.e., removal of more material than is needed, in lower-density regions of the IC. In some cases, such as where there are weak spots or defects in the dielectric layers that electrically isolate respective metal interconnect features, over-etching may compromise the integrity of the dielectric layers, which may result in current leakage paths and/or unwanted via formation through the dielectric layers.

A potential source of weakness in interconnect-level dielectric films is the presence of a hillock in an underlying metal feature, such as a metal interconnect line. A hillock is a topological defect characterized by a localized elevated region of the metal feature. Hillocks may form at various points during the semiconducting manufacturing process, and may be difficult to detect and/or eliminate. A hillock in a metal interconnect feature may produce localized elevated regions in other material layers, such as interconnect-level dielectric layers. These localized elevated regions may be subsequently deposited over the metal interconnect feature. These localized elevated regions in the dielectric layer(s) may produce weak spots in the dielectric material that etch at a higher rate than the surrounding material. Accordingly, these areas may be vulnerable to the formation of unwanted via openings through the dielectric layer(s). Such unwanted via openings may result in unwanted electrical shorts between metal features of the interconnect structure, which may render the IC defective.

Various embodiments of the present disclosure are directed to interconnect structures and methods of forming interconnect structures that provide decreased risk of unwanted via formation through interconnect-level dielectric layers. In various embodiments, following the formation of first metal interconnect feature(s) in a first metal level of the interconnect structure, a first set of one or more interconnect-level dielectric layers may be formed over the metal interconnect feature(s). Conductive vias may optionally be formed through the first set of interconnect-level dielectric layers to connect metal interconnect features of the first metal level to metal interconnect features in other metal levels that may be subsequently formed. Then, a planarization process may be performed to remove localized elevated regions from the upper-most surface of the first set of one or more interconnect-level dielectric layers. The local elevated regions may be caused by hillocks in the underlying first metal interconnect features. Following the planarization process, a second set of one or more interconnect-level dielectric layers may be deposited over the planarized upper surface of the first set of one or more dielectric layers. An etching process may be performed to form trenches extending through the second set of one or more interconnect-level dielectric layers and into the first set of one or more interconnect-level dielectric layers. Second metal interconnect features of a second metal level of the interconnect structure may be formed in the trenches. By removing the localized elevated regions from the upper-most surface of the first set of one or more interconnect-level dielectric layers prior to depositing the second set of interconnect-level dielectric layers, weak spots in the dielectric material, which may be caused by hillocks in the underlying metal features, may be avoided. Accordingly, trenches for additional metal interconnect features may be formed in the second set of interconnect-level dielectric layers with minimal risk of over-etch through to the underlying metal level. Even in instances in which there is a significant over-etch into the underlying interconnect-level dielectric layer(s), the etching rate through the dielectric material may be relatively uniform, and unwanted via formation may be avoided. This may improve overall device functionality and yield.

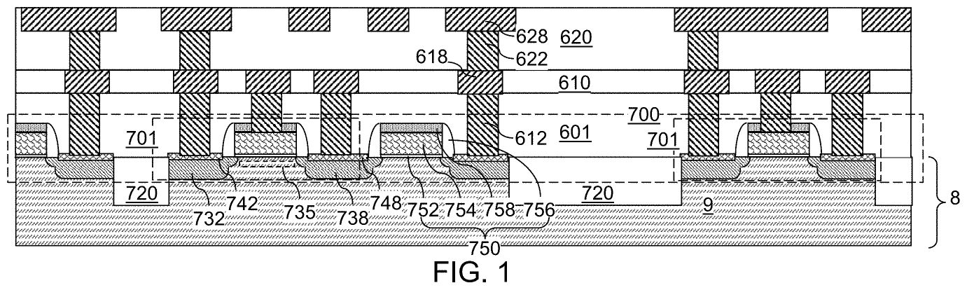

Referring to FIG. 1, a first exemplary structure according to a first embodiment of the present disclosure is illustrated. The first exemplary structure includes a substrate 8, which may be a semiconductor substrate. In embodiments, the substrate 8 may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 701 may be formed over the top surface of the semiconductor material layer 9. For example, each field effect transistor 701 may include a source electrode 732, a drain electrode 738, a semiconductor channel 735 that includes a surface portion of the substrate 8 extending between the source electrode 732 and the drain electrode 738, and a gate structure 750. The semiconductor channel 735 may include a single crystalline semiconductor material. Each gate structure 750 may include a gate dielectric layer 752, a gate electrode 754, a gate cap dielectric 758, and a dielectric gate spacer 756. A source-side metal-semiconductor alloy region 742 may be formed on each source electrode 732, and a drain-side metal-semiconductor alloy region 748 may be formed on each drain electrode 738.

The devices formed on the top surface of the semiconductor material layer 9 may include complementary metal-oxide-semiconductor (CMOS) transistors and optionally additional semiconductor devices (such as resistors, diodes, capacitors, etc.), and are collectively referred to as CMOS circuitry 700. While planar CMOS transistors are illustrated in FIG. 1, other transistors types, e.g., FinFET, thin-film transistors (TFT), etc. may be formed on the substrate 8.

Various metal interconnect structures formed within dielectric layers may be subsequently formed over the substrate 8 and the semiconductor devices thereupon (such as field effect transistors 701). In an illustrative example, the dielectric layers may include, for example, a first dielectric layer 601 that may be a layer that surrounds the contact structure connected to the source and drains (sometimes referred to as a contact-level dielectric layer 601), a first interconnect-level dielectric layer 610, and a second interconnect-level dielectric layer 620. The metal interconnect structures may include device contact via structures 612 formed in the first dielectric layer 601 and contact a respective component of the CMOS circuitry 700, first metal line structures 618 formed in the first interconnect-level dielectric layer 610, first metal via structures 622 formed in a lower portion of the second interconnect-level dielectric layer 620, and second metal line structures 628 formed in an upper portion of the second interconnect-level dielectric layer 620.

Each of the dielectric layers (601, 610, 620) may include a dielectric material such as undoped silicate glass, a doped silicate glass, organosilicate glass, amorphous fluorinated carbon, porous variants thereof, or combinations thereof. Each of the metal interconnect structures (612, 618, 622, 628) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process.

In various embodiments, one or more additional interconnect-level dielectric layers (e.g., a third interconnect-level dielectric layer, a fourth interconnect-level dielectric layer, etc.) may be formed over the second interconnect-level dielectric layer 620, and various metal interconnect structures, such as metal via structures and metal line structures, may be formed in the respective interconnect-level dielectric layers. The metal interconnect structures located within the interconnect-level dielectric layers may be configured to route electrical signals to and from, and/or in between, various devices, which may include CMOS circuitry 700 formed on the semiconductor material layer 9. In some embodiments, additional devices, which may include thin-film transistors (not shown in FIG. 1), may optionally be formed within one or more inter-connect level dielectric layers of the exemplary structure. Metal interconnect structures may be electrically coupled to additional devices that are optionally formed in an interconnect-level dielectric layer. Moreover, while FIG. 1 illustrates three (3) dielectric layers 601, 610, 620, additional dielectric layers may be formed having metal interconnect structures formed therein.

The various devices formed on an exemplary structure as shown in FIG. 1 may include, without limitation, logic devices, memory devices (e.g., RAM), image sensors (e.g., CMOS image sensors), and/or display devices (e.g., an LED or LCD display device).

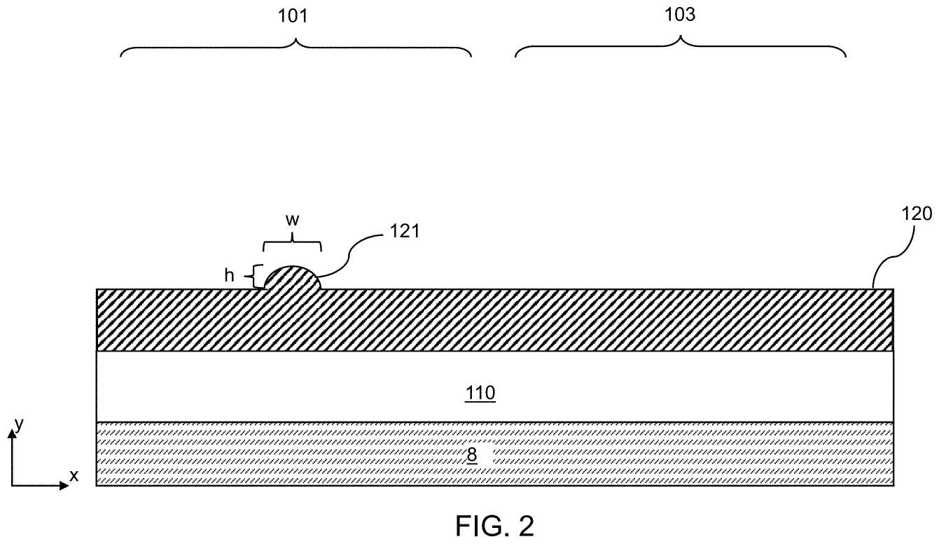

FIGS. 2-15 are sequential vertical cross-sectional views showing an exemplary structure of a portion of an integrated circuit (IC) device during a process of forming metal interconnect structures according to an embodiment of the present disclosure. Referring to FIG. 2, the exemplary structure may be similar to the exemplary structure shown in FIG. 1, and may include a substrate 8, such as a semiconductor substrate, a dielectric layer 110 over the substrate 8, and a first metal interconnect feature 120, such as a metal line, over the dielectric layer 110. In embodiments, the first metal interconnect feature 120 may be embedded in the dielectric layer 110 such that the metal interconnect structure is laterally surrounded (i.e., along the x-axis direction) by dielectric layer 110 material. Various other features shown in the exemplary structure of FIG. 1, such as field effect transistor devices 701, shallow-trench isolation structures 720, device contact via structures 612, and the like, may also be present in the exemplary structure, but are not illustrated in FIG. 2 for purposes of clarity.

Referring again to FIG. 2, dielectric layer 110 may be formed of a suitable dielectric material, such as silicon oxide (SiO₂) silicon nitride (SiN, Si₃N₄), silicon carbide (SiC), undoped silicate glass (USG), a doped silicate glass, organosilicate glass, amorphous fluorinated carbon, porous variants thereof, or combinations thereof. Other dielectric materials are within the contemplated scope of disclosure. The dielectric layer 110 may be deposited using any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like.

The first metal interconnect feature 120 may be formed of any suitable electrically conductive material, such as copper (Cu), tungsten (W), aluminum (Al), aluminum copper (AlCu), aluminum silicon copper (AlSiCu), cobalt (Co), ruthenium (Ru), molybdenum (Mo), tantalum (Ta), titanium (Ti), alloys thereof, combinations thereof, or the like. Other electrically conductive materials are within the contemplated scope of disclosure. In some embodiments, the first metal interconnect feature 120 may include a barrier layer (such as a metallic nitride or a metallic carbide layer) and a metallic fill material. The barrier layer (not shown in FIG. 2) may include a layer of TiN, TaN, WN, TiC, TaC, and WC, or combinations thereof, that may be formed over the surface of the dielectric layer 110. Other barrier layer materials are within the contemplated scope of disclosure. The metallic filler may then be deposited over the barrier layer. The first metal interconnect feature 120, including the optional barrier layer and the metallic fill material, may be formed using a suitable deposition process, which may include one or more of a chemical vapor deposition (CVD) process, a physical vapor deposition (PVD) process, an atomic layer deposition (ALD) process, an electroplating process, or the like. Other suitable deposition processes are within the contemplated scope of disclosure.

Referring again to FIG. 2, the upper surface of the first metal interconnect feature 120 may include one or more hillocks 121. A hillock is a topological defect characterized by a localized elevated region of the metal material relative to the remaining surface of the metal interconnect feature 120, which may be a planar surface. Hillocks in metal interconnect features 120, such as metal lines, may be generated due to thermal stresses resulting from high temperature processing steps used during semiconductor manufacturing processes. In some cases, hillocks 121 may have width (w) and/or height (h) dimension of 50 nm or more.

FIG. 2 also illustrates a first region 101 of the exemplary structure in which a second metal interconnect feature (e.g., a metal line) may be subsequently formed. FIG. 2 also illustrates a second region 103 of the exemplary structure in which a third metal interconnect feature (e.g., a metal line) may be subsequently formed. The second metal interconnect feature and the third metal interconnect feature may be separated from the first metal interconnect feature 120 along the vertical (i.e., y-axis) direction by an interconnect-level dielectric layer that may also be subsequently formed over the first metal interconnect feature 120.

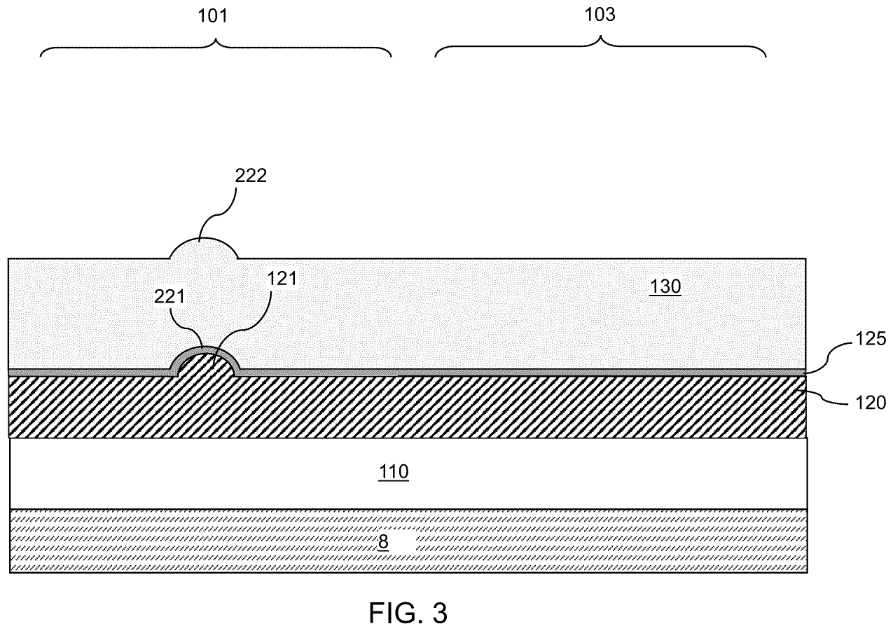

FIG. 3 is a vertical cross-section view of the exemplary structure showing a first dielectric layer 125 formed over the first metal interconnect feature 120, and a second dielectric layer 130 formed over the first dielectric layer 125. The first dielectric layer 125 may be composed of a dielectric material that is different than the dielectric material of the second dielectric layer 130. The material of the first dielectric layer 125 may have a higher etch resistance to an etch chemistry that may be used in a subsequent etching step than the etch resistance of the material of the second dielectric layer 130. Accordingly, the first dielectric layer 125 may also be referred to as an etch stop dielectric layer. In some embodiments, the first dielectric layer 125 may include silicon nitride, silicon carbide nitride, silicon oxynitride, or a dielectric metal oxide such as aluminum oxide. Other suitable dielectric materials for the first dielectric layer 125 are within the contemplated scope of disclosure.

The second dielectric layer 130 may include a silicon oxide material, which may take the form of undoped silicate glass (USG). Other suitable dielectric materials are within the contemplated scope of disclosure, including without limitation, a doped silicate glass, organosilicate glass, amorphous fluorinated carbon, a low-k dielectric material, porous variants thereof, or combinations thereof.

The first dielectric layer 125 and the second dielectric layer 130 may be deposited using suitable deposition processes, such as chemical vapor deposition (CVD) process, a physical vapor deposition (PVD) process, an atomic layer deposition (ALD) process, a high-density plasma CVD (HDPCVD) process, a low-pressure CVD process, a metalorganic CVD (MOCVD) process, a plasma enhanced CVD (PECVD) process, a sputtering process, laser ablation, or the like. Other suitable deposition processes are within the scope of disclosure. In various embodiments, the second dielectric layer 130 may have a greater thickness than the thickness of the first dielectric layer 125.

Referring again to FIG. 3, the first dielectric layer 125 may include a localized elevated region 221, and the second dielectric layer 130 may also include a localized elevated region 222. Each of the localized elevated regions 221 and 222 may be located above the location of the hillock 121 in the first metal interconnect feature 120. A hillock 121 in a metal interconnect feature may produce localized elevated regions 221, 222 in other material layers, such as interconnect-level dielectric layers 125, 130, that are subsequently deposited over the metal interconnect feature. These localized elevated regions 221, 222 in the subsequently-formed first dielectric layer 125 and the second dielectric layer 130 may result in non-uniform etching rates through the first dielectric layer 125 and the second dielectric layer 130. For example, during a subsequent etching step, the etch rate through portions of the first dielectric layer 125 and the second dielectric layer 130, such as around the periphery of the elevated regions 221, 222, may be greater than the etch rate elsewhere through the first dielectric layer 125 and the second dielectric layer 130. In some cases, this may result in over-etching and the creation of current leakage paths and/or the formation of unwanted via(s) through the first dielectric layer 125 and the second dielectric layer 130. As described in further detail below, various embodiments include methods of fabricating an interconnect structure for an integrated circuit that minimize the risk of current leakage and unwanted via formation between metal features due to hillock defects.

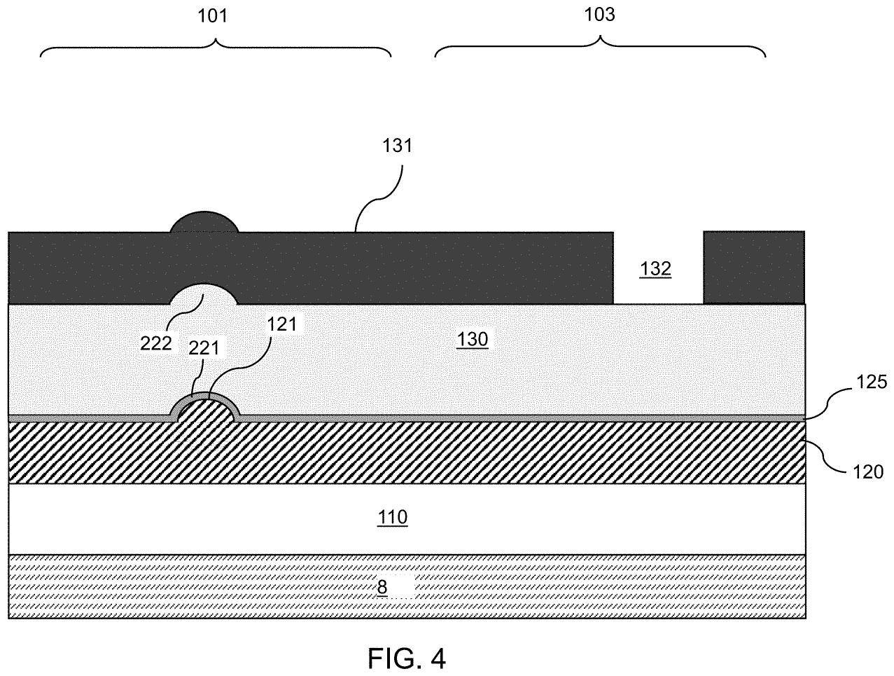

FIG. 4 is a vertical cross-section view of the exemplary structure showing a patterned mask 131 over the upper surface of the second dielectric layer 130. Referring to FIG. 4, the patterned mask 131 may be lithographically patterned to form at least one opening 132 through the mask 131. Each opening 132 in the mask 131 may correspond to the location of a via opening that may be subsequently formed through the first dielectric layer 125 and the second dielectric layer 130. In the exemplary structure shown in FIG. 4, the patterned mask 131 includes an opening 132 in the second region 103 of the exemplary structure, and does not include an opening in the first region 101 of the exemplary structure.

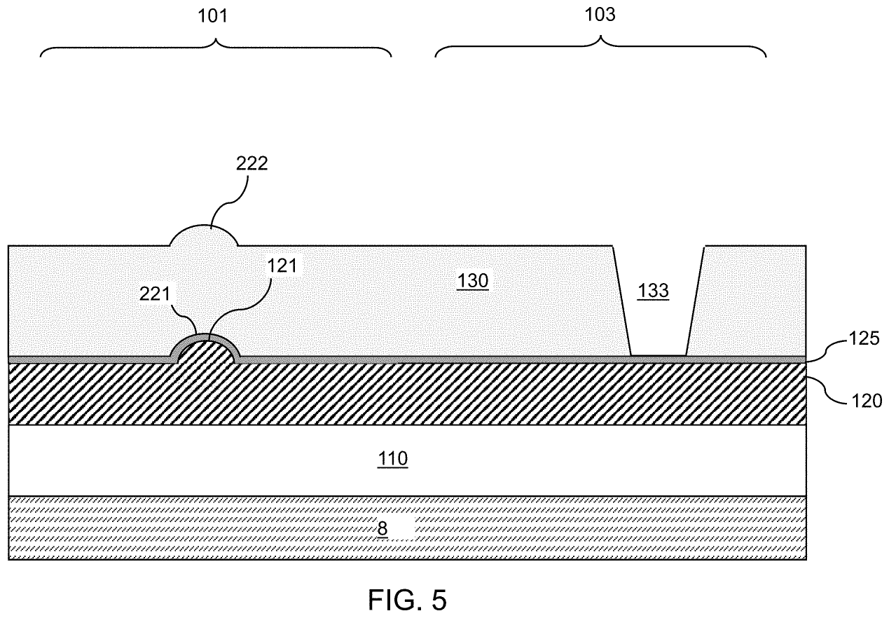

FIG. 5 is a vertical cross-section view of the exemplary structure showing a via opening 133 formed through the second dielectric layer 130. Referring to FIG. 5, an anisotropic etch process may be performed through the patterned mask 131 to remove portions of the second dielectric layer 130 and form a via opening 133 through the dielectric layer 130. The etch process may stop at the first dielectric layer 125, which as discussed above, may also be referred to as an etch stop dielectric layer. Following the etch process, the patterned mask 131 may be removed using a suitable process, such as by ashing or dissolution with a solvent.

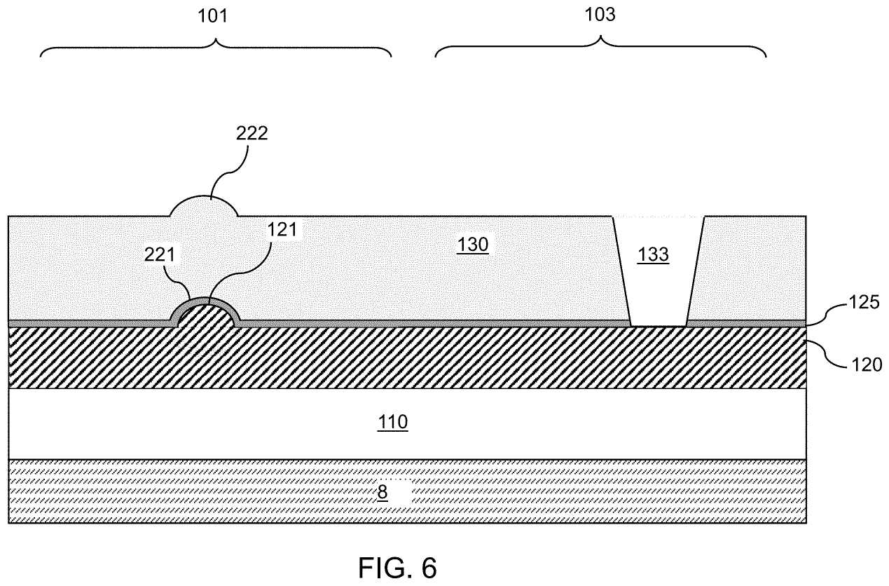

FIG. 6 is a vertical cross-section view of the exemplary structure showing the via opening 133 extended through the first dielectric layer 125 to expose an upper surface of the first metal interconnect feature 120. Referring to FIG. 6, the first dielectric layer 125 may be etched through the via opening 133 to remove a remaining portion of the first dielectric layer 125 at the bottom of the via opening 133 and expose the upper surface of the first metal interconnect feature 120. In some embodiments, the etching process used to form the via opening 133 through the second dielectric layer 130 may use a different etch chemistry than the etching process used to extend the via opening through the first dielectric layer 125. Alternatively, both of these etching processes may utilize the same etch chemistry and/or may be performed in a single etching step.

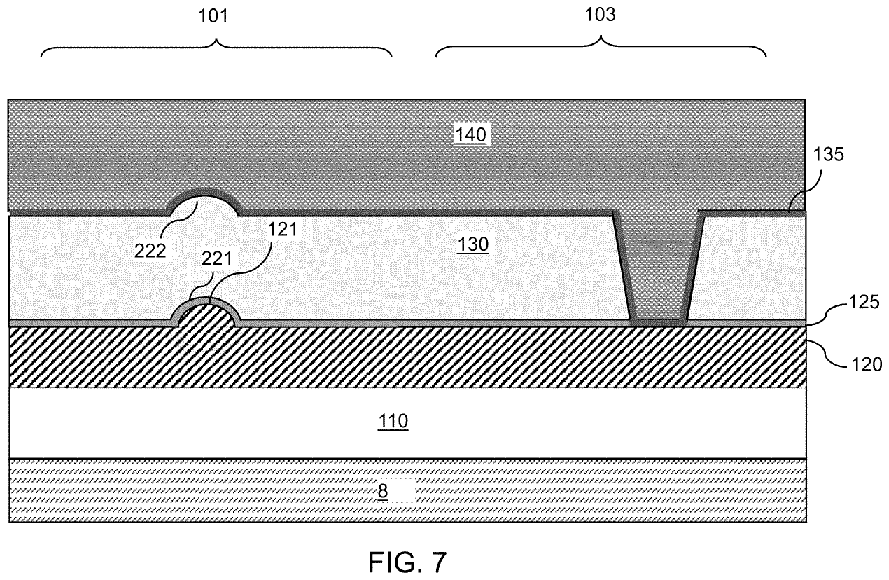

FIG. 7 is a vertical cross-section view of the exemplary structure showing a barrier layer 135 deposited on the second dielectric layer 130 and the sidewalls and bottom surface of the via opening 133. A metallic fill layer 140 may be deposited over the upper surface of the barrier layer 135, filling a remaining volume of the via opening 133. Referring to FIG. 7, the barrier layer 135 may be deposited over the upper surface of the second dielectric layer 130 and over the sidewalls and the bottom surface of the via opening 133 such that the barrier layer 135 contacts the exposed surface of the first metal interconnect feature 120 at the bottom of the via opening 133. The barrier layer 135 may include TiN, TaN, W, Ti, Ta, combinations thereof, or the like. Other suitable barrier layer materials, such as metal, metallic nitride and/or metallic carbide materials, are within the contemplated scope of disclosure. In various embodiments, the barrier layer 135, may provide a barrier to diffusion of the material of the metallic fill layer into the surrounding dielectric material. The barrier layer 135 may also provide effective adherence to the metallic fill material that is subsequently deposited over the barrier layer 135. The barrier layer 135 may be formed as a single layer or as a multi-layer structure. The barrier layer 135 may be formed using a suitable deposition process, such as one or more of a chemical vapor deposition (CVD) process, a physical vapor deposition (PVD) process, an atomic layer deposition (ALD) process, an electroplating process, or the like. Other suitable deposition processes are within the contemplated scope of disclosure.

Referring again to FIG. 7, the metallic fill layer 140 may be deposited as a continuous layer over the upper surface of the barrier layer 135 and within the via opening 133. The metallic fill layer 140 may include an electrically conductive material, such as copper (Cu), tungsten (W), aluminum (Al), aluminum copper (AlCu), aluminum silicon copper (AlSiCu), cobalt (Co), ruthenium (Ru), molybdenum (Mo), tantalum (Ta), titanium (Ti), alloys thereof, combinations thereof, or the like. Other electrically conductive materials are within the contemplated scope of disclosure. In some embodiments, the metallic fill layer 140 may include the same electrically conductive material as the first metal interconnect feature 120. Alternatively, the electrically conductive material of the metallic fill layer 140 may be different than the electrically conductive material of the first metal interconnect feature 120. For example, the metallic fill layer 140 may include different element(s) than the material of the first metal interconnect feature 120, or the metallic fill layer 140 may include the same elements but at different atomic concentrations than the material of the first metal interconnect feature 120. The metallic fill layer 140 may be formed using a suitable deposition process, such as one or more of a chemical vapor deposition (CVD) process, a physical vapor deposition (PVD) process, an atomic layer deposition (ALD) process, an electroplating process, or the like. Other suitable deposition processes are within the contemplated scope of disclosure.

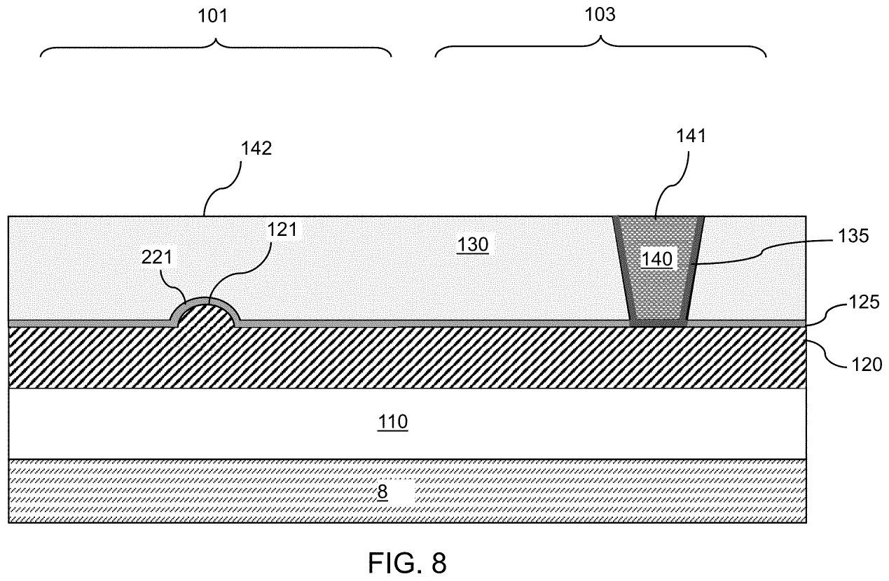

FIG. 8 is a vertical cross-section view of the exemplary structure after a planarization process to remove the elevated region 222 of the second dielectric layer 130 and portions of the metallic fill layer 140 and the barrier layer 135 from above the upper surface of the second dielectric layer 130. Referring to FIG. 8, the exemplary structure may undergo a planarization process, such as a chemical mechanical planarization (CMP) process. The planarization process may remove the metallic fill layer 140 and the barrier layer 135 from above an upper surface of the second dielectric layer 130. The remaining portions of the metallic fill layer 140 and the barrier layer 135 located within the via opening 133 may form a conductive via 141 that contacts the upper surface of the first metal interconnect feature 120. The upper surface of the conductive via 141 may be co-planar with the upper surface of the second dielectric layer 130.

Referring again to FIG. 8, the planarization process may also remove the elevated region 222 of the second dielectric layer 130 overlying the hillock 121 of the first metal interconnect feature 120. Following the planarization process which removes the elevated region 222, the second dielectric layer 130 may have a planar upper surface 142. The hillock 121 of the first metal interconnect feature 120 and the elevated region 221 of the first dielectric layer 125 may remain underlying the planar upper surface 142 of the second dielectric layer 130.

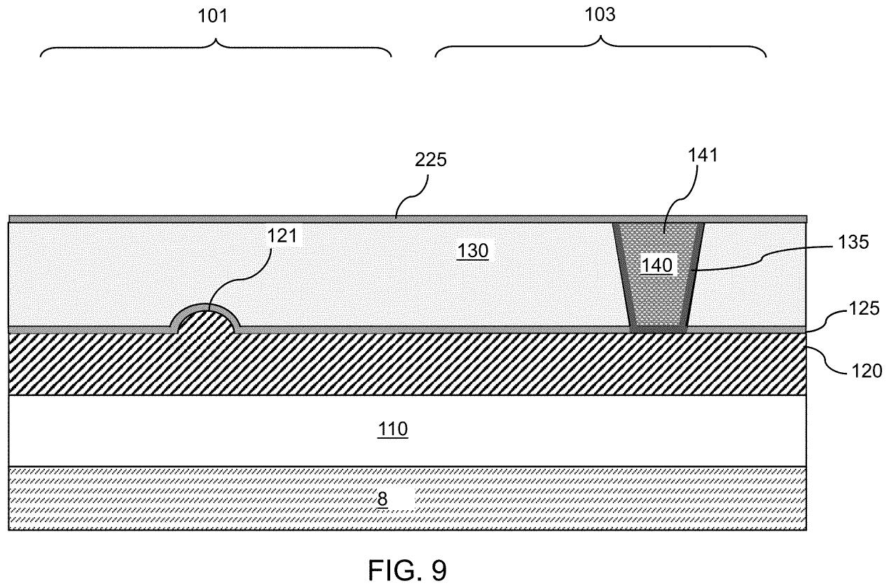

FIG. 9 is a vertical cross-section view of the exemplary structure showing a third dielectric layer 225 formed over the second dielectric layer 130 and the conductive via 141. Referring to FIG. 9, the third dielectric layer 225 may be conformally deposited over the upper surface of the second dielectric layer. The material of the third dielectric layer 225 may have a higher etch resistance to an etch chemistry that may be used in a subsequent etching step than the etch resistance of the material of a fourth dielectric layer that may be subsequently formed over the third dielectric layer 225. Thus, the third dielectric layer 225 may also be referred to as an etch stop dielectric layer. In some embodiments, the third dielectric layer 225 may include silicon nitride, silicon carbide nitride, silicon oxynitride, or a dielectric metal oxide such as aluminum oxide. Other suitable dielectric materials for the third dielectric layer 225 are within the contemplated scope of disclosure. In some embodiments, the third dielectric layer 225 may be composed of the same material as the first dielectric layer 125. Alternatively, the third dielectric layer 225 may be composed of a different material than the first dielectric layer 125. The third dielectric layer 225 may be deposited using suitable deposition processes, such as chemical vapor deposition (CVD) process, a physical vapor deposition (PVD) process, an atomic layer deposition (ALD) process, a high-density plasma CVD (HDPCVD) process, a low-pressure CVD process, a metalorganic CVD (MOCVD) process, a plasma enhanced CVD (PECVD) process, a sputtering process, laser ablation, or the like. Other suitable deposition processes are within the scope of disclosure.

Referring again to FIG. 9, the third dielectric layer 225, including the portion of the third dielectric layer 225 overlying the hillock 121 in the first metal interconnect feature 120, may have a planar upper surface. In various embodiments, by performing a planarization process to remove the elevated region 222 of the second dielectric layer 130 prior to depositing additional layers over the second dielectric layer 130, the additional layers formed over the second dielectric layer 130 may have planar upper surfaces that do not include an elevated region overlying the hillock 121. This may help to prevent over-etching due to non-uniform film topology in subsequent etching steps. In addition, this may minimize the risk of leakage paths and/or unwanted vias forming between the first metal interconnect feature 120 and overlying metal feature(s) that may be subsequently formed.

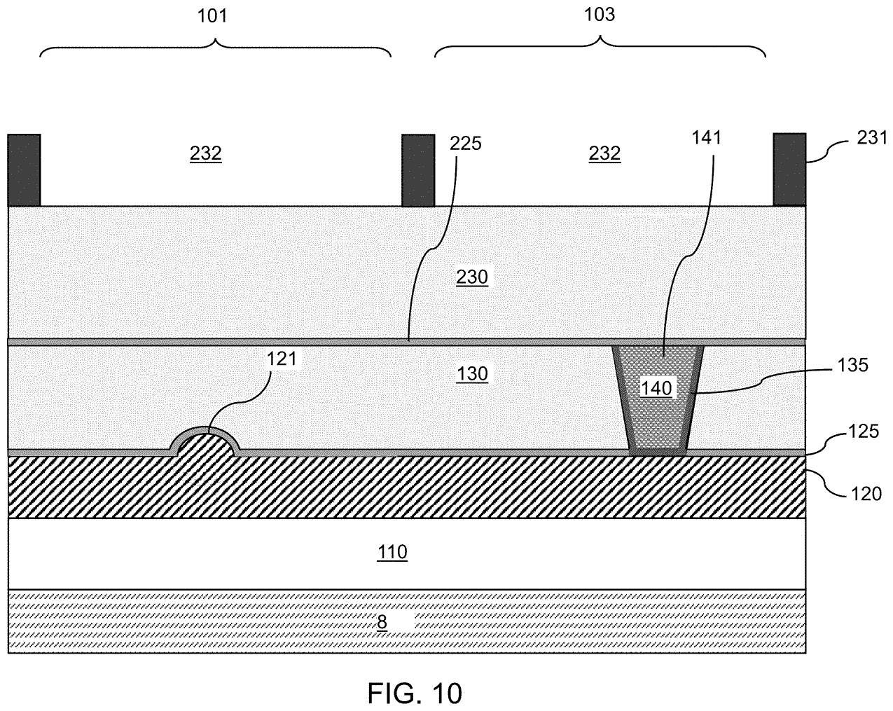

FIG. 10 is a vertical cross-section view of the exemplary structure showing a fourth dielectric layer 230 formed over an upper surface of the third dielectric layer 225, and a patterned mask 231 formed over the fourth dielectric layer 230. Referring to FIG. 10, the fourth dielectric layer 230 may be conformally deposited over the upper surface of the third dielectric layer 225. The fourth dielectric layer 230 may include a silicon oxide material, which may take the form of undoped silicate glass (USG). Other dielectric materials for the fourth dielectric layer 230 are within the contemplated scope of disclosure, including without limitation, a doped silicate glass, organosilicate glass, amorphous fluorinated carbon, a low-k dielectric material, porous variants thereof, or combinations thereof. In embodiments, the fourth dielectric layer 230 may be composed of the same material as the second dielectric layer 130. Alternatively, the fourth dielectric layer 230 may be composed of a different material than the second dielectric layer 130. The fourth dielectric layer 230 may be deposited using suitable deposition processes, such as chemical vapor deposition (CVD) process, a physical vapor deposition (PVD) process, an atomic layer deposition (ALD) process, a high-density plasma CVD (HDPCVD) process, a low-pressure CVD process, a metalorganic CVD (MOCVD) process, a plasma enhanced CVD (PECVD) process, a sputtering process, laser ablation, or the like. Other suitable deposition processes are within the scope of disclosure. In various embodiments, the fourth dielectric layer 230 may have a greater thickness than the thickness of the third dielectric layer 225. The fourth dielectric layer 230, including the portion of the fourth dielectric layer 230 overlying the hillock 121 in the first metal interconnect feature 120, may have a planar upper surface.

Referring again to FIG. 10, a patterned mask 231 may be formed over the upper surface of the fourth dielectric layer 230. The mask 231 may be lithographically patterned to form at least one opening 232 through the mask 231. Each opening 232 in the mask 231 may correspond to the location of a trench that may be subsequently formed through the third dielectric layer 225 and the fourth dielectric layer 230. In the exemplary structure shown in FIG. 10, the patterned mask 231 includes an opening 232 in each of the first region 101 and the second region 103 of the exemplary structure.

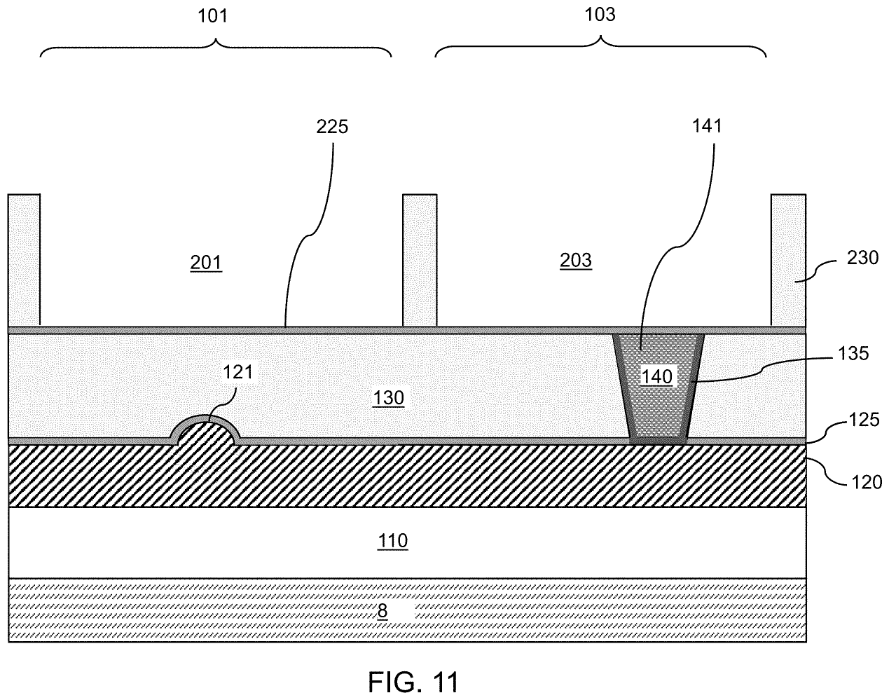

FIG. 11 is a vertical cross-section view of the exemplary structure showing trench 201 formed in the first region 101 and trench 203 formed in the second region 103 of the exemplary structure. Referring to FIG. 11, an anisotropic etch process may be performed through the patterned mask 231 to remove portions of the fourth dielectric layer 230 and form trenches 201, 203 in the fourth dielectric layer 230. The etch process may stop at the third dielectric layer 225, which may be an etch stop dielectric layer. Following the etch process, the patterned mask 231 may be removed using a suitable process, such as by ashing or dissolution with a solvent.

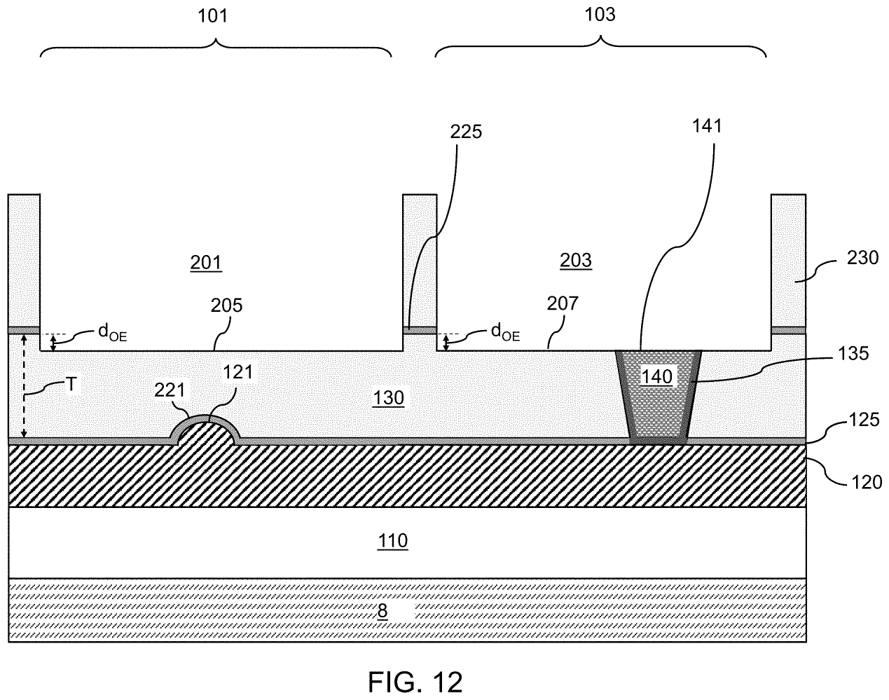

FIG. 12 is a vertical cross-section view of the exemplary structure showing the trenches 201, 203 extended through the third dielectric layer 225 and into the second dielectric layer 130. Referring to FIG. 12, an anisotropic etching process may be used to remove portions of the third dielectric layer 225 from the bottom of trenches 201 and 203. The etching process may continue beyond the lower surface of the third dielectric layer 225 to remove portions of the second dielectric layer 130 underlying the trenches 201 and 203. The etching process (e.g., over-etch) may also remove portions of the conductive via 141 (i.e., barrier layer 135 and metallic fill 140) in trench 203. Thus, the depth of each of the trenches 201 and 203 may extend beyond the lower surface of the third dielectric layer 225 by a vertical distance, d_{OE}, as shown in FIG. 12.

The vertical distance, d_{OE}, between the lower surface of the third dielectric layer 225 and the bottom surfaces of the respective trenches 201, 203 may be referred to as the over-etch depth of the trenches. In various embodiments, in order to address the pattern density loading effect described above, the etching recipe may be tuned to minimize or eliminate instances of under-etching in regions of the integrated circuit device having the highest pattern density. Accordingly, in other regions of the integrated circuit device having relatively lower pattern densities, the etching process may result in an over-etch into the underlying dielectric layer(s). The over-etch depth, d_{OE}, in various regions of the integrated circuit device may vary as a function of the pattern density within the respective region. In some regions of the integrated circuit device having a relatively lower pattern density, the over etch depth, d_{OE}, may be at least about 10%, such as at least about 20%, of the total thickness, T, of the second dielectric layer 130 between the first dielectric layer 125 and the third dielectric layer 225. In other embodiments, the over etch depth, d_{OE}, may be at least about 5% and as much as 35% of the total thickness, T, of the second dielectric layer 130 between the first dielectric layer 125 and the third dielectric layer 225.

Following the etching process, the surface 205 of the trench 201 overlying the hillock 121 and the elevated region 221 of the first dielectric layer 125 may be planar, and may not include any unwanted via openings through second dielectric layer 130. Due to the planar topography of the upper surfaces of the third dielectric layer 225 and the second dielectric layer 130, the surface 205 of the trench 201 may not have any weak spots. In addition, the etching rate through the third dielectric layer 225 and into the second dielectric layer 130 may be relatively uniform across the surface 205 of the trench 201. In some embodiments, following the etching process, the surface 205 of the trench 201 within the first region 101 may be substantially co-planar with the surface 207 of the adjacent trench 203 within the second region 103.

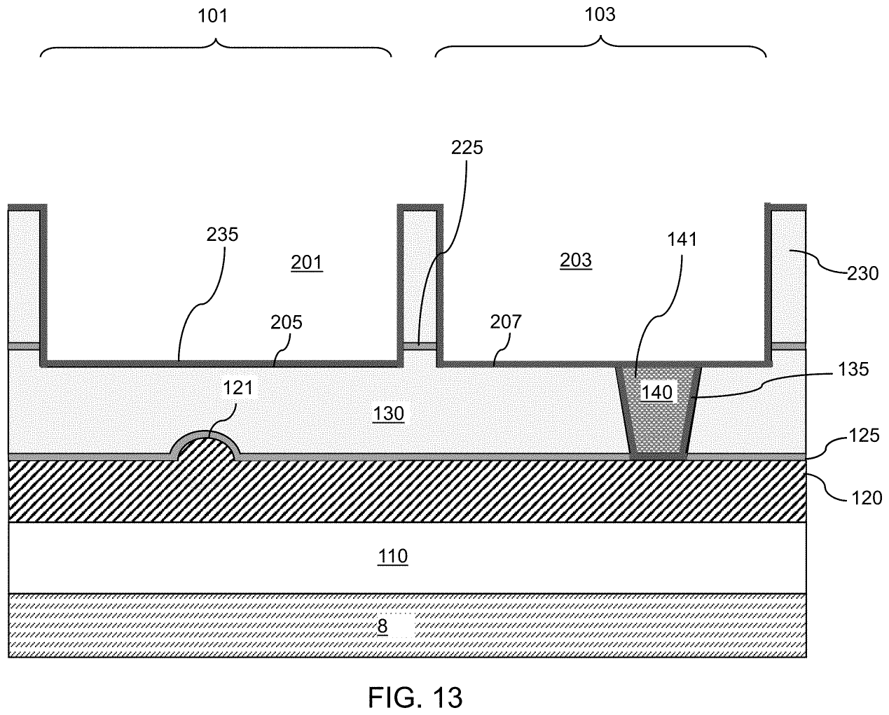

FIG. 13 is a vertical cross-section view of the exemplary structure showing a barrier layer 235 on the fourth dielectric layer 230 and on the sidewalls and surfaces 205, 207 of respective trenches 201 and 203. Referring to FIG. 13, the barrier layer 235 may be conformally deposited over the upper surface of the fourth dielectric layer 230 and over the sidewalls and surfaces 205 and 207 of each of the trenches 201 and 203. As shown in FIG. 13, the barrier layer 235 may contact the exposed surface of the conductive via 141 along the surface 207 of the trench 203 in the second region 103. The barrier layer 235 may include TiN, TaN, W, Ti, Ta, combinations thereof, or the like. Other suitable barrier layer materials, such as metal, metallic nitride and/or metallic carbide materials, are within the contemplated scope of disclosure. The barrier layer 235 may be composed of the same material(s) as barrier layer 135, or alternatively may be composed of different material(s) than barrier layer 135. The barrier layer 235 may be formed as a single layer or as a multi-layer structure. The barrier layer 235 may be formed using a suitable deposition process, such as one or more of a chemical vapor deposition (CVD) process, a physical vapor deposition (PVD) process, an atomic layer deposition (ALD) process, an electroplating process, or the like. Other suitable deposition processes are within the contemplated scope of disclosure.

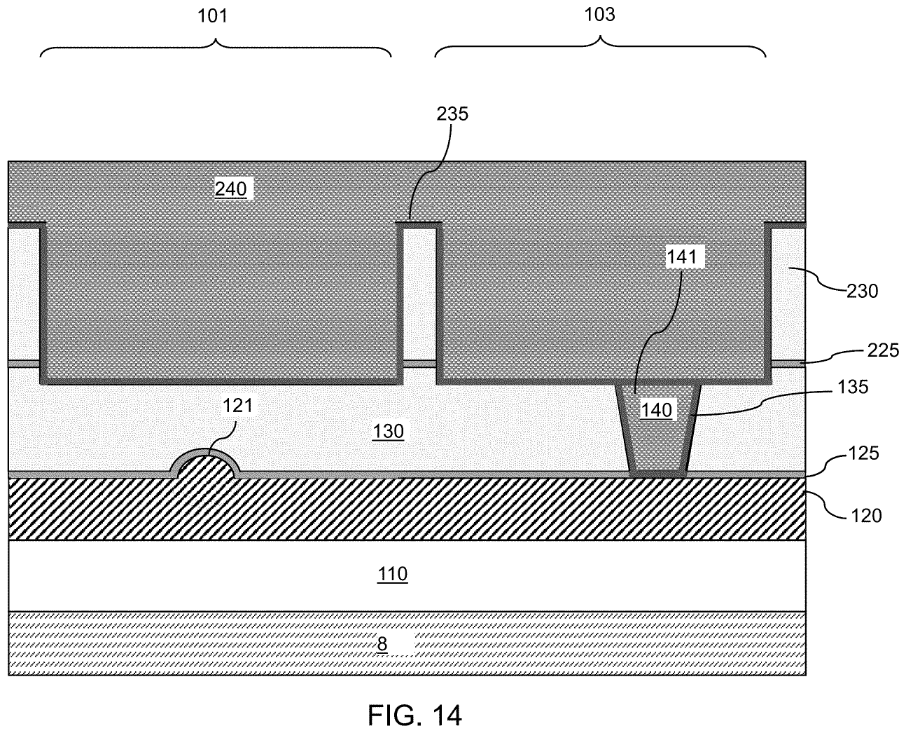

FIG. 14 is a vertical cross-section view of the exemplary structure showing a metallic fill layer 240 deposited over the upper surface of the barrier layer 235 and filling a remaining volume of the trenches 201 and 203. Referring to FIG. 14, the metallic fill layer 240 may be deposited as a continuous layer over the upper surface of the barrier layer 235 and within each of the trenches 201 and 203 in regions 101 and 103, respectively. The metallic fill layer 240 may include an electrically conductive material, such as copper (Cu), tungsten (W), aluminum (Al), aluminum copper (AlCu), aluminum silicon copper (AlSiCu), cobalt (Co), ruthenium (Ru), molybdenum (Mo), tantalum (Ta), titanium (Ti), alloys thereof, combinations thereof, or the like. Other electrically conductive materials are within the contemplated scope of disclosure. In some embodiments, the metallic fill layer 240 may include the same electrically conductive material as the metallic fill material 140 of the conductive via 141. Alternatively, the electrically conductive material of metallic fill layer 240 may be different than the metallic fill material 140 of the conductive via 141. The metallic fill layer 240 may be formed using a suitable deposition process, such as one or more of a chemical vapor deposition (CVD) process, a physical vapor deposition (PVD) process, an atomic layer deposition (ALD) process, an electroplating process, or the like. Other suitable deposition processes are within the contemplated scope of disclosure.

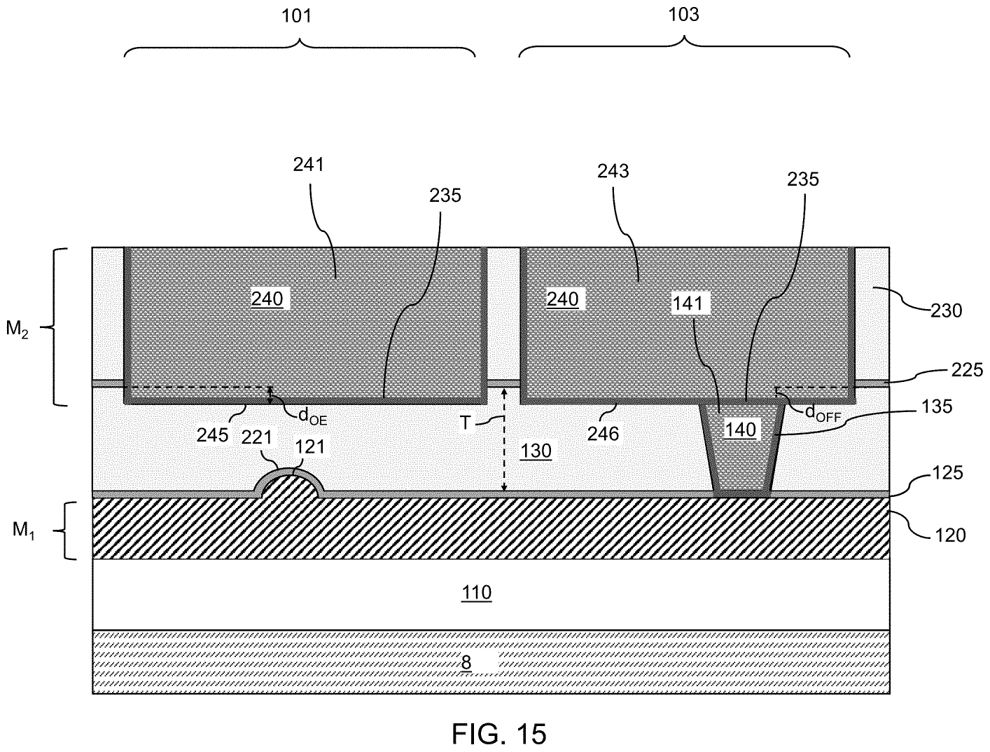

FIG. 15 is a vertical cross-section view of the exemplary structure showing a second metal interconnect feature 241 formed in the first region 101 of the exemplary structure and a third metal interconnect feature 243 formed in the second region 103 of the exemplary structure. Referring to FIG. 15, the exemplary structure may undergo a planarization process, such as a chemical mechanical planarization (CMP) process. The planarization process may remove the metallic fill layer 240 and the barrier layer 235 from above an upper surface of the fourth dielectric layer 230. The remaining portions of the metallic fill layer 240 and the barrier layer 235 located within trenches 201 and 203 may form second interconnect feature 241 and third metal interconnect feature 243, respectively. The upper surfaces of both the second interconnect feature 241 and the third metal interconnect feature 243 may be co-planar with the upper surface of the fourth dielectric layer 230.

The second metal interconnect feature 241, which may be a metal line, may be located in the first region 101 of the exemplary structure. The second metal interconnect feature 241 may be located over the first metal interconnect feature 120 and may be vertically separated from the first metal interconnect feature 120 by the first dielectric layer 125 and the second dielectric layer 130. The first dielectric layer 125 and the second dielectric layer 130 may extend continuously between the first metal interconnect feature 120 and the second metal interconnect feature 230 such that there is no direct current path between the first metal interconnect feature 120 and the second metal interconnect feature 241 through the first dielectric layer 125 and the second dielectric layer 130. The second metal interconnect feature 241 may have a planar bottom surface 245. The planar bottom surface 245 of the second metal interconnect feature 241 may overlie any hillocks 121 present in the first metal interconnect feature 120 and any localized elevated regions 221 of the first dielectric layer 125 overlying the hillock(s) 121. In some embodiments, the bottom surface 245 of the second metal interconnect feature 241 may be below a plane containing the bottom surface of the third dielectric layer 235. Accordingly, the second metal interconnect feature 241 may be laterally surrounded by the fourth dielectric layer 230, the third dielectric layer 225 and a portion of the second dielectric layer 130. In various embodiments, the vertical distance, d_{OE}, between the bottom surface of the third dielectric layer 225 and the bottom surface of the second metal interconnect feature 241 may be at least about 10%, such as at least about 20%, of the total thickness, T, of the second dielectric layer 130 between the first dielectric layer 125 and the third dielectric layer 225.

The third metal interconnect feature 243, which may be a metal line, may be located in the second region 103 of the exemplary structure. The third metal interconnect feature 243 may contact the upper surface of the conductive via 141 to form a conductive pathway between the third metal interconnect feature 243 and the first metal interconnect feature 120. In some embodiments, a portion of the barrier layer 235 may extend across the upper surface of the conductive via 141 and may vertically separate the metallic fill material 240 of the third interconnect feature 243 from the metallic fill material 140 of the conductive via 141. In some embodiments, the portion of the barrier layer 235 extending across the upper surface of the conductive via 141 may have an upper surface that is below a plane containing the bottom surface of the third dielectric layer 235. In various embodiments, the vertical offset distance, d_{OFF}, between the bottom surface of the third dielectric layer 235 and the upper surface of the barrier layer 235 may be at least about 10%, such as at least about 20%, of the total thickness, T, of the second dielectric layer 130 between the first dielectric layer 125 and the third dielectric layer 225.

The third metal interconnect feature 243 may have a planar bottom surface 246. In embodiments, the planar bottom surface 246 of the third metal interconnect feature 243 may be co-planar with the bottom surface 245 of the adjacent second metal interconnect feature 241 located in the first region 101. The third metal interconnect feature 243 may be laterally surrounded by the fourth dielectric layer 230, the third dielectric layer 225 and a portion of the second dielectric layer 130.

In some embodiments, the second metal interconnect feature 241 and the third metal interconnect feature 243 may be located within a second metal level (M₂) of the interconnect structure that may be located over a first metal level (M₁) that includes the first metal interconnect feature 120. The first metal level (M₁) and the second metal level (M₂) may be vertically separated from each other by dielectric layers 125, 130. One or more conductive vias 141 may extend through the dielectric layers 125, 130 to electrically connect metal features of the first metal level (M₁) to metal features of the second metal level (M₂). In embodiments, additional metal levels (e.g., M₃, M₄, etc.) may be formed over the second metal level (M₂). In various embodiments, the additional metal levels may be formed using a process as shown and described with reference to FIGS. 2-15.

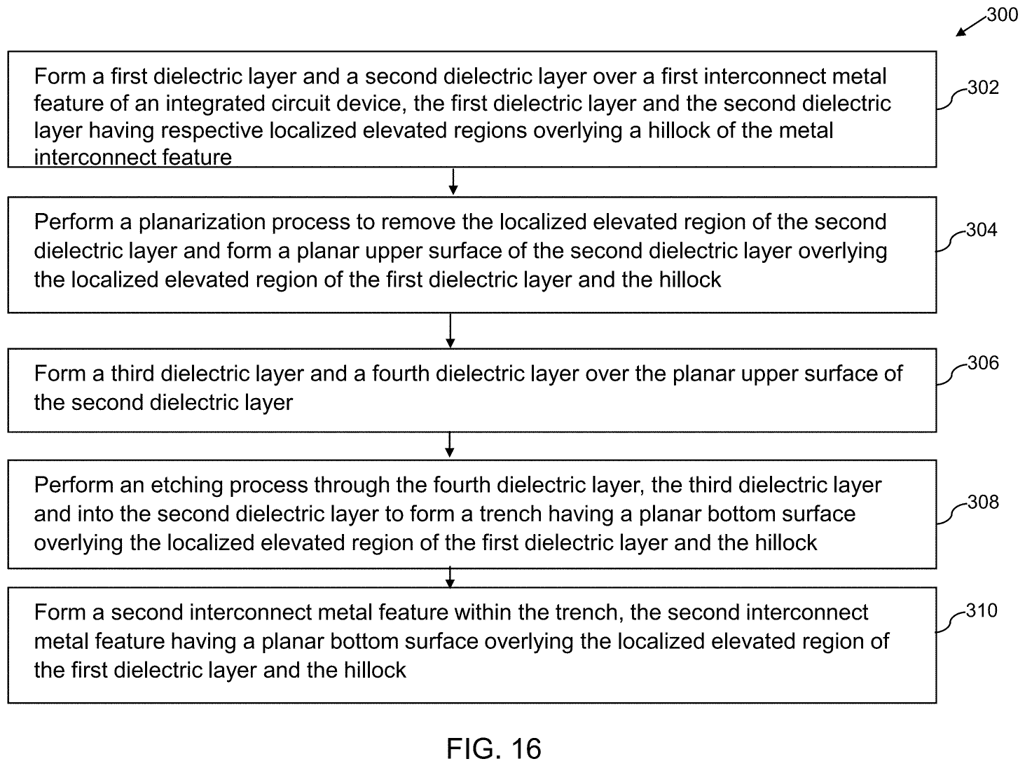

FIG. 16 is a flow chart showing a method 300 of forming an interconnect structure for an integrated circuit device. Referring to FIGS. 3 and 16, in step 302 of method 300, a first dielectric layer 125 and a second dielectric layer 130 may be formed over a first metal interconnect feature 120 of an integrated circuit device. The first dielectric layer 125 and the second dielectric layer 130 may each have respective localized elevated regions 221, 222 overlying a hillock 121 of the first metal interconnect feature 120. Referring to FIGS. 8 and 16, in step 304 of method 300, a planarization process may be performed to remove the localized elevated region 222 of the second dielectric layer 130 so as to form a planar upper surface of the second dielectric layer 130 overlying the localized elevated region 221 of the first dielectric layer 125 and the hillock 121. Referring to FIGS. 9, 10 and 16, in step 306 of method 300, a third dielectric layer 225 and a fourth dielectric layer 230 may be formed over the planar upper surface of the second dielectric layer 130. Referring to FIGS. 11, 12 and 16, in step 308 of method 300, an etching process may be performed through the fourth dielectric layer 230, the third dielectric layer 225 and into the second dielectric layer 130 to form a trench 201 having a planar bottom surface 205 overlying the localized elevated region 222 of the first dielectric layer 125 and the hillock 121. Referring to FIGS. 13-16, in step 310 of method 300, a second metal interconnect feature 241 may be formed within the trench 201. The second metal interconnect feature 241 may have a planar bottom surface 245 overlying the localized elevated region 222 of the first dielectric layer 125 and the hillock 121.

Referring to all drawings and according to various embodiments of the present disclosure, method of forming an interconnect structure for an integrated circuit device includes forming a first dielectric layer 125 and a second dielectric layer 130 over a first metal interconnect feature 120 of the integrated circuit device, where the first dielectric layer 125 and the second dielectric layer 130 each include respective localized elevated regions 221, 222 overlying a hillock 121 of the first metal interconnect feature 120, performing a planarization process to remove the localized elevated region 222 of the second dielectric layer 130 and form a planar upper surface 142 of the second dielectric layer 130 overlying the local elevated region 221 of the first dielectric layer 125 and the hillock 121, forming a third dielectric layer 225 and a fourth dielectric layer 230 over the planar upper surface 142 of the second dielectric layer 130, performing an etching process through the fourth dielectric layer 230, the third dielectric layer 225, and into the second dielectric layer 130 to form a trench 201 having a planar bottom surface 205 overlying the localized elevated region 221 of the first dielectric layer 125 and the hillock 121, and forming a second metal interconnect feature 241 within the trench 201, the second metal interconnect feature 241 having a planar bottom surface 245 overlying the localized elevated region 221 of the first dielectric layer 125 and the hillock 121.

In an embodiment, the hillock 121 may have at least one of a height and a width dimension of at least 50 nm.

In another embodiment, the first dielectric layer 125 and the third dielectric layer 225 may be etch stop dielectric layers having a higher etch resistance to an etch chemistry used during the etching process than the second dielectric layer 130 and the fourth dielectric layer 230, the second dielectric layer 130 and the fourth dielectric layer 230 having a greater thickness than the first dielectric layer 125 and the third dielectric layer 225.

In another embodiment, performing the etching process includes etching into the second dielectric layer 130 to form the trench 201 such that a depth of the surface 205 of the trench 201 beneath a bottom surface of the third dielectric layer 225 is at least about 10% of a total thickness of the second dielectric layer 130.

In another embodiment, the second metal interconnect feature 241 may be formed in a first region 101 of the integrated circuit device, and the method further includes, prior to performing the planarization process, performing an etching process through the second dielectric layer 130 and the first dielectric layer 125 to form a via opening 133 in a second region 103 of the integrated circuit device, and forming a conductive via 141 in the via opening 133.

In another embodiment, forming a conductive via 141 includes depositing a barrier layer 135 over an upper surface of the second dielectric layer 130, over the sidewalls of the via opening 133, and over an exposed portion of the first metal interconnect feature 120 at the bottom of the via opening 133, and depositing a metallic fill layer 140 over the barrier layer 135 and within a remaining volume of the via opening 133, where the planarization process removes portions of the barrier layer 133 and the metallic fill layer 140 from above an upper surface of the second dielectric layer 130.

In another embodiment, the trench 201 formed in the first region 101 of the integrated circuit device is a first trench, and wherein performing the etching process further includes etching through the fourth dielectric layer 230, the third dielectric layer 225, and into the second dielectric layer 130 to form a second trench 203 in the second region 103 of the integrated circuit device, the second trench 203 having a planar bottom surface 207 that exposes an upper surface of the conductive via 141, and a third metal interconnect structure 243 is formed within the second trench 203.

In another embodiment, forming the second metal interconnect structure 241 and the third metal interconnect structure 243 includes depositing a barrier layer 235 over an upper surface of the fourth dielectric layer 230, and over the sidewalls and the bottom surfaces of each of the first and second trenches 201, 203, depositing a metallic fill layer 240 over the barrier layer 235 and within the remaining volumes of the first and second trenches 201, 203, and performing a planarization process to remove the barrier layer 235 and the metallic fill layer 240 from over an upper surface of the fourth dielectric layer 230 to form the second metal interconnect structure 241 in the first trench 201 and the third metal interconnect structure 243 in the second trench 203, where the third metal interconnect structure 243 is electrically connected to the first metal interconnect structure 120 by the conductive via 141, and the second metal interconnect structure 241 is electrically isolated from the first metal interconnect structure 120 by the second dielectric layer 130 and the first dielectric layer 125.

Another embodiment is drawn to an interconnect structure for an integrated circuit device that includes a first metal interconnect feature 120 having a hillock 121, a first dielectric layer 125 over the first metal interconnect feature 120, the first dielectric layer having a localized elevated region 221 overlying the hillock 121, a second dielectric layer 130 over the first dielectric layer 125, a third dielectric layer 225 over the second dielectric layer 130, a fourth dielectric layer 230 over the third dielectric layer 225, and a second metal interconnect feature 241 having a planar bottom surface 245 overlying the localized elevated region 221 of the first dielectric layer 125 and the hillock 121 of the first metal interconnect feature 120, the second metal interconnect feature 241 laterally surrounded by the fourth dielectric layer 230, the third dielectric layer 225, and a portion of the second dielectric layer 130, and the second dielectric layer 130 and the first dielectric layer 125 extend continuously between the first metal interconnect feature 120 and the planar bottom surface 245 of the second metal interconnect feature 241.

In an embodiment, a vertical distance between the planar bottom surface 245 of the second metal interconnect feature 241 and a bottom surface of the third dielectric layer 225 is at least about 10% of a total thickness of the second dielectric layer 130 between the first dielectric layer 125 and the third dielectric layer 225.

In another embodiment, the vertical distance between the planar bottom surface 245 of the second metal interconnect feature 241 and the bottom surface of the third dielectric layer 225 may be at least about 20% of a total thickness of the second dielectric layer 130 between the first dielectric layer 125 and the third dielectric layer 225.

In another embodiment, the hillock 121 may have at least one of a height and a width dimension of at least 50 nm.

In another embodiment, the first dielectric layer 125 and the third dielectric layer 225 may be etch stop dielectric layers, and the second dielectric layer 130 and the fourth dielectric layer 230 may have a greater thickness than the first dielectric layer 125 and the third dielectric layer 225.

In another embodiment, the first dielectric layer 125 and the third dielectric layer 225 may include silicon nitride, and the second dielectric layer 130 and the fourth dielectric layer 230 may include undoped silicate glass.

In another embodiment, the interconnect structure may further include a third metal interconnect feature 243 overlying the first metal interconnect feature 120, the third metal interconnect feature 243 laterally surrounded by the fourth dielectric layer 230, the third dielectric layer 225, and a portion of the second dielectric layer 130, and a conductive via 141 extends between the third metal interconnect feature 243 and the first metal interconnect feature 120, the conductive via 141 laterally surrounded by the second dielectric layer 130 and the first dielectric layer 125.

In another embodiment, each of the second metal interconnect feature 241 and the third metal interconnect feature 243 include a barrier layer 235 and a metallic fill material 240, the barrier layer 235 extending between the metallic fill material 240 and each of the fourth dielectric layer 230, the third dielectric layer 225 and the second dielectric layer 230.

In another embodiment, the barrier layer 235 of the third metal interconnect feature 243 extends over an upper surface of the conductive via 141, and wherein an upper surface of the barrier layer 235 is located below a lower surface of the third dielectric layer 225.

Another embodiment is drawn to an interconnect structure for an integrated circuit device that includes a first metal interconnect feature 120, a first dielectric layer 125 over the first metal interconnect feature, a second dielectric layer 130 over the first dielectric layer 125, a third dielectric layer 225 over the second dielectric layer 130, a fourth dielectric layer 230 over the third dielectric layer 225, and a third metal interconnect feature 243 above the first metal interconnect feature 120 and electrically connected to the first metal interconnect feature 120 by a conductive via 141 extending through the first dielectric layer 125 and the second dielectric layer 130, the third metal interconnect feature 243 laterally surrounded by the fourth dielectric layer 230, the third dielectric layer 225, and a portion of the second dielectric layer 130, and where the third metal interconnect feature 243 includes a barrier layer 235 and a metallic fill material 240, a portion of the barrier layer 235 extends between the metallic fill material 240 and an upper surface of the conductive via 141, and a vertical offset distance between a bottom surface of the third dielectric layer 225 and an upper surface of the portion of the barrier layer 235 extending over the upper surface of the conductive via 141 is at least about 10% of a total thickness of the second dielectric layer 130.

In an embodiment, the barrier layer 235 and the metallic fill material 140 may be composed of different materials, and the barrier layer 235 includes at least one of TiN, TaN, W, Ti, and Ta and the metallic fill material 240 includes at least one Cu, W, Al, AlCu, AlSiCu, Co, Ru, Mo, Ta, and Ti.

In another embodiment, the first dielectric layer 125 and the third dielectric layer 225 include silicon nitride, and the second dielectric layer 130 and the fourth dielectric layer 230 include undoped silicate glass.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming an interconnect structure for an integrated circuit device, comprising:
forming a first dielectric layer and a second dielectric layer over a first metal interconnect feature of the integrated circuit device, where the first dielectric layer and the second dielectric layer each include respective localized elevated regions overlying a hillock of the first metal interconnect feature;
performing a planarization process to remove the localized elevated region of the second dielectric layer and form a planar upper surface of the second dielectric layer overlying the localized elevated region of the first dielectric layer and the hillock;
forming a third dielectric layer and a fourth dielectric layer over the planar upper surface of the second dielectric layer;
performing an etching process through the fourth dielectric layer, the third dielectric layer, and into the second dielectric layer to form a trench having a planar bottom surface overlying the localized elevated region of the first dielectric layer and the hillock; and
forming a second metal interconnect feature within the trench, the second metal interconnect feature having a planar bottom surface overlying the localized elevated region of the first dielectric layer and the hillock.

2. The method of claim 1, wherein the hillock has at least one of a height and a width dimension of at least 50 nm.

3. The method of claim 1, wherein the first dielectric layer and the third dielectric layer are etch stop dielectric layers having a higher etch resistance to an etch chemistry used during the etching process than the second dielectric layer and the fourth dielectric layer, the second dielectric layer and the fourth dielectric layer having a greater thickness than the first dielectric layer and the third dielectric layer.

4. The method of claim 1, wherein performing the etching process comprises etching into the second dielectric layer to form the trench such that a depth of the bottom surface of the trench beneath a bottom surface of the third dielectric layer is at least about 10% of a total thickness of the second dielectric layer.

5. The method of claim 1, wherein the second metal interconnect feature is formed in a first region of the integrated circuit device, and the method further comprises:
prior to performing the planarization process, performing an etching process through the second dielectric layer and the first dielectric layer to form a via opening in a second region of the integrated circuit device; and
forming a conductive via in the via opening.

6. The method of claim 5, wherein forming a conductive via comprises:
depositing a barrier layer over an upper surface of the second dielectric layer, over sidewalls of the via opening, and over an exposed portion of the first metal interconnect feature at the bottom of the via opening; and
depositing a metallic fill layer over the barrier layer and within a remaining volume of the via opening, wherein the planarization process removes portions of the barrier layer and the metallic fill layer from above an upper surface of the second dielectric layer.

7. The method of claim 6, wherein the trench formed in the first region of the integrated circuit device is a first trench, and wherein performing the etching process further comprises etching through the fourth dielectric layer, the third dielectric layer, and into the second dielectric layer to form a second trench in the second region of the integrated circuit device, the second trench having a planar bottom surface that exposes an upper surface of the conductive via, and a third metal interconnect structure is formed within the second trench.

8. The method of claim 7, wherein forming the second metal interconnect structure and the third metal interconnect structure comprises:
depositing a barrier layer over an upper surface of the fourth dielectric layer, and over the sidewalls and the bottom surfaces of each of the first and second trenches;
depositing a metallic fill layer over the barrier layer and within the remaining volumes of the first and second trenches; and
performing a planarization process to remove the barrier layer and the metallic fill layer from over an upper surface of the fourth dielectric layer to form the second metal interconnect structure in the first trench and the third metal interconnect structure in the second trench, wherein the third metal interconnect structure is electrically connected to the first metal interconnect structure by the conductive via, and the second metal interconnect structure is electrically isolated from the first metal interconnect structure by the second dielectric layer and the first dielectric layer.

9. An interconnect structure for an integrated circuit device, comprising:
a first metal interconnect feature having a hillock;
a first dielectric layer over the first metal interconnect feature, the first dielectric layer having a localized elevated region overlying the hillock;
a second dielectric layer over the first dielectric layer;
a third dielectric layer over the second dielectric layer;
a fourth dielectric layer over the third dielectric layer; and
a second metal interconnect feature having a planar bottom surface overlying the localized elevated region of the first dielectric layer and the hillock of the first metal interconnect feature, the second metal interconnect feature laterally surrounded by the fourth dielectric layer, the third dielectric layer, and a portion of the second dielectric layer, and the second dielectric layer and the first dielectric layer extend continuously between the first metal interconnect feature and the planar bottom surface of the second metal interconnect feature.

10. The interconnect structure of claim 9, wherein a vertical distance between the planar bottom surface of the second metal interconnect feature and a bottom surface of the third dielectric layer is at least about 10% of a total thickness of the second dielectric layer between the first dielectric layer and the third dielectric layer.

11. The interconnect structure of claim 10, wherein the vertical distance between the planar bottom surface of the second metal interconnect feature and the bottom surface of the third dielectric layer is at least about 20% of a total thickness of the second dielectric layer between the first dielectric layer and the third dielectric layer.

12. The interconnect structure of claim 9, wherein the hillock has at least one of a height and a width dimension of at least 50 nm.

13. The interconnect structure of claim 9, wherein the first dielectric layer and the third dielectric layer comprise etch stop dielectric layers, and the second dielectric layer and the fourth dielectric layer have a greater thickness than the first dielectric layer and the third dielectric layer.

14. The interconnect structure of claim 13, wherein the first dielectric layer and the third dielectric layer comprise silicon nitride, and the second dielectric layer and the fourth dielectric layer comprise undoped silicate glass.

15. The interconnect structure of claim 9, further comprising a third metal interconnect feature overlying the first metal interconnect feature, the third metal interconnect feature laterally surrounded by the fourth dielectric layer, the third dielectric layer, and a portion of the second dielectric layer, and a conductive via extends between the third metal interconnect feature and the first metal interconnect feature, the conductive via laterally surrounded by the second dielectric layer and the first dielectric layer.

16. The interconnect structure of claim 15, wherein each of the second metal interconnect feature and the third metal interconnect feature comprise a barrier layer and a metallic fill material, the barrier layer extending between the metallic fill material and each of the fourth dielectric layer, the third dielectric layer and the second dielectric layer.

17. The interconnect structure of claim 16, wherein the barrier layer of the second metal interconnect feature extends over an upper surface of the conductive via, and wherein an upper surface of the barrier layer is located below a lower surface of the third dielectric layer.

18. An interconnect structure for an integrated circuit device, comprising:
a first metal interconnect feature;
a first dielectric layer over the first metal interconnect feature;
a second dielectric layer over the first dielectric layer;
a third dielectric layer over the second dielectric layer;
a fourth dielectric layer over the third dielectric layer; and
a third metal interconnect feature above the first metal interconnect feature and electrically connected to the first metal interconnect feature by a conductive via extending through the first dielectric layer and the second dielectric layer, the third metal interconnect feature laterally surrounded by the fourth dielectric layer, the third dielectric layer, and a portion of the second dielectric layer, wherein:
the third metal interconnect feature comprises a barrier layer and a metallic fill material, a portion of the barrier layer extends between the metallic fill material and an upper surface of the conductive via, and a vertical offset distance between a bottom surface of the third dielectric layer and an upper surface of the portion of the barrier layer extending over the upper surface of the conductive via is at least about 10% of a total thickness of the second dielectric layer.

19. The interconnect structure of claim 18, wherein the barrier layer and the metallic fill material are composed of different materials, and the barrier layer comprises at least one of TiN, TaN, W, Ti, and Ta and the metallic fill material comprises at least one Cu, W, Al, AlCu, AlSiCu, Co, Ru, Mo, Ta, and Ti.

20. The interconnect structure of claim 19, wherein the first dielectric layer and the third dielectric layers comprise silicon nitride, and the second dielectric layer and the fourth dielectric layer comprise undoped silicate glass.
